(19) United States
(12) Patent Application Publication
(10) Pub. No.: US 2008/0303550 A1
(43) Pub. Date: Dec. 11, 2008

(54) INTEGRATED CIRCUIT WITH PLURAL LEVEL SHIFTERS

(75) Inventors: Chun-Hsiung CHEN, Hsinchu City (TW); Chun-Ku LIN, Hsinchu County (TW); Wen-Liang LIU, Hsinchu City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: HOLTEK SEMICONDUCTOR INC., Hsinchu (TW)

(21) Appl. No.: 12/047,497

(22) Filed: Mar. 13, 2008

(30) Foreign Application Priority Data
Jun. 5, 2007 (TW) 096120225

(51) Int. Cl. H03K 19/0175

(52) U.S. Cl. 326/63

(57) ABSTRACT

An integrated circuit is provided. The integrated circuit includes N level shifting devices. Each level shifting device receives a first digital signal and a second digital signal, and includes a first level shifter converting a first voltage of the first digital signal into a third voltage and converting a second voltage of the first digital signal into a fourth voltage, and a second level shifter converting a first voltage of the second digital signal into a fifth voltage and converting a second voltage of the second digital signal into a sixth voltage.

### FIELD OF THE INVENTION

The present invention relates to an integrated circuit, and more particularly to an integrated circuit with plural level shifters.

### BACKGROUND OF THE INVENTION

The level shifter is a well-known electronic component widely applied in various kinds of circuits. Some level shifters may be made as integrated circuits (ICs). Usually, a single IC chip only has a level shifter. Some IC chips have two level shifters with two different voltage outputs. However, a single IC chip cannot have more than one level shifter with the same voltage output. Therefore, when two or more level shifters with different levels are needed, it is necessary to use two or more level shifter ICs. This will occupy more space of the printed circuit board (PCB) and thus increase the cost. Besides, using two or more level shifters needs more connecting wires, thereby reducing the reliability. Moreover, the power consumption is increased since two or more level shifters are used simultaneously.

In order to overcome the drawbacks in the prior art, an integrated circuit with plural level shifters is provided. The particular design in the present invention not only solves the problems described above, but also is easy to be implemented. Thus, the present invention has the utility for the industry.

### SUMMARY OF THE INVENTION

It is an aspect of the present invention to provide 2N level shifters in an integrated circuit or an integrated circuit package, wherein N level shifters will convert the voltage of the input digital signal into output voltages with different levels, and the other N level shifters will convert the voltage of the input digital into a plurality of output voltages which can be set by the user. External pins are provided for setting the plurality of output voltages. N is an integer greater than or equal to 2.

In accordance with another aspect of the present invention, an integrated circuit is provided. The integrated circuit includes N level shifting devices. Each level shifting device receives a first digital signal and a second digital signal, and includes a first level shifter converting a first voltage of the first digital signal into a third voltage and converting a second voltage of the first digital signal into a fourth voltage, and a second level shifter converting a first voltage of the second digital signal into a fifth voltage and converting a second voltage of the second digital signal into a sixth voltage.

Preferably, the integrated circuit further includes at least one logic circuit receiving the first digital signal and electrically connected to the first level shifter.

Preferably, the logic circuit further receives the second digital signal and is electrically connected to the second level shifter.

Preferably, the logic circuit is electrically connected to a low voltage protecting device.

Preferably, the integrated circuit further includes a first driver electrically connected to the first level shifter and outputting the third voltage and the fourth voltage.

Preferably, the integrated circuit further includes a second driver electrically connected to the second level shifter and outputting the fifth voltage and the sixth voltage.

Preferably, N is an integer greater than or equal to 2.

Preferably, the first voltage of the first signal and the second voltage of the first signal are input voltages of the first level shifter.

Preferably, the first voltage of the first digital signal is a low level voltage, and the second voltage of the first digital signal is a high level voltage.

Preferably, the first voltage of the first digital signal is a logic “0” signal, and the second voltage of the first digital signal is a logic “1” signal.

Preferably, the first voltage of the first digital signal is a logic “1” signal, and the second voltage of the first digital signal is a logic “0” signal.

Preferably, the third voltage and the fourth voltage are output voltages of the first level shifter.

Preferably, the third voltage is a low level voltage, and the fourth voltage is a high level voltage.

Preferably, the third voltage is a logic “0” signal, and the fourth voltage is a logic “1” signal.

Preferably, the third voltage is a logic “1” signal, and the fourth voltage is a logic “0” signal.

Preferably, the first voltage of the second digital signal and the second voltage of the second digital signal are input voltages of the second level shifter.

Preferably, the first voltage of the second digital signal is a low level voltage, and the second voltage of the second digital signal is a high level voltage.

Preferably, the first voltage of the second digital signal is a logic “0” signal, and the second voltage of the second digital signal is a logic “1” signal.

Preferably, the first voltage of the second digital signal is a logic “1” signal, and the second voltage of the second digital signal is a logic “0” signal.

Preferably, the fifth voltage and the sixth voltage are output voltages of the second level shifter.

Preferably, the fifth voltage is a low level voltage, and the sixth voltage is a high level voltage.

Preferably, the fifth voltage is a logic “0” signal, and the sixth voltage is a logic “1” signal.

Preferably, the fifth voltage is a logic “1” signal, and the sixth voltage is a logic “0” signal.

In accordance with a further aspect of the present invention, an integrated circuit package is provided. The integrated circuit includes N level shifting devices. Each level shifting device receives a first digital signal and a second digital signal, and includes a first level shifter converting a first voltage of the first digital signal into a third voltage and converting a second voltage of the first digital signal into a fourth voltage, and a second level shifter converting a first voltage of the second digital signal into a fifth voltage and converting a second voltage of the second digital signal into a sixth voltage.

In accordance with further another aspect of the present invention, an integrated circuit is provided. The integrated circuit includes N level shifting devices. Each level shifting device receives a first digital signal and a second digital signal, and includes a first level shifter electrically connected to a high level pin and a low level pin, wherein the high level pin is provided for the first level shifter to output a first high level voltage while the low level pin is provided for the first level shifter to output a first low level voltage, and a second level shifter electrically connected to a first pin and a second pin, wherein the first pin is provided for the second level shifter to output a second high level voltage while the second pin is provided for the second level shifter to output a second low level voltage.

Preferably, the integrated circuit further includes at least one logic circuit receiving the first digital signal and electrically connected to the first level shifter.

Preferably, the logic circuit further receives the second digital signal and is electrically connected to the second level shifter.

Preferably, the logic circuit is electrically connected to a low voltage protecting device.

Preferably, the integrated circuit further includes a positive power pin and a negative power pin.

Preferably, the positive power pin and the negative power pin provide powers for the first digital signal, wherein the powers are provided for the logic circuit to decide whether the first digital signal is a high level or a low level.

Preferably, the positive power pin and the negative power pin provide powers for the second digital signal, wherein the powers are provided for the logic circuit to decide whether the second digital signal is a high level or a low level.

Preferably, N is an integer greater than or equal to 2.

In accordance with further another aspect of the present invention, an integrated circuit package is provided. The integrated circuit includes N level shifting devices. Each integrated circuit receives a first digital signal and a second digital signal, and includes a first level shifter electrically connected to a high level pin and a low level pin, wherein the high level pin is provided for the first level shifter to output a first high level voltage while the low level pin is provided for the first level shifter to output a first low level voltage, and a second level shifter electrically connected to a first pin and a second pin, wherein the first pin is provided for the second level shifter to output a second high level voltage while the second pin is provided for the second level shifter to output a second low level voltage.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a schematic diagram showing the structure of the integrated circuit according to a preferred embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

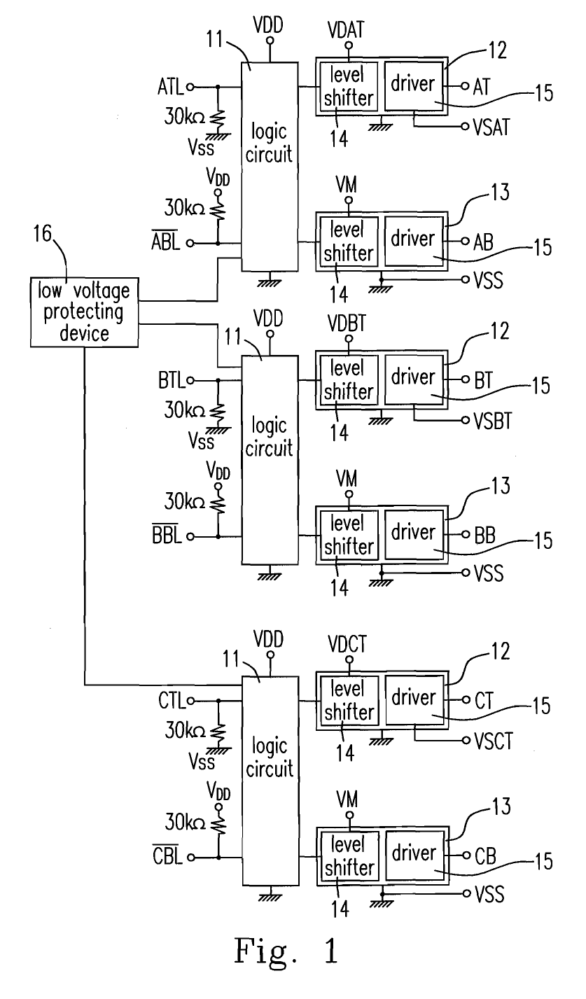

Please refer to FIG. 1, which is a schematic diagram showing the structure of the integrated circuit according to a preferred embodiment of the present invention. The integrated circuit includes six level shifters 14, six digital signal input pins ATL, BTL, CTL, ABL, BBL, CBL, six drivers 15, three logic circuits 11 and a low voltage protecting device 16. The digital signal inputs of three level shifters 14 will be converted into three digital signal outputs with different voltages, wherein the setting of the mentioned digital signal outputs is determined by the external power input pins VM, VSS. The digital signal inputs of the other three level shifters 14 will be converted into three digital signal outputs with voltages that can be set by the user, wherein the set voltages are input via external pins. Therefore, there are three different external high level voltage inputs (pins VDAT, VDBT, VDCT) and three different external low level voltage inputs (pins VSAT, VSBT, VSCT) in this embodiment.

In FIG. 1, three drivers 15 and three level shifters 14 constitute three high side drivers 12 respectively, while the other three drivers 15 and the other three level shifters 14 constitute three low side drivers 13 respectively.

ATL, ABL, BTL, BBL, CTL, CBL are the digital signal input pins of the six level shifters 14 respectively.

AB, BB, CB are the digital signal output pins of the three level shifters 14, wherein AB is the output pin corresponding to the digital signal input pin ABL, BB is the output pin corresponding to the digital signal input pin BBL, and CB is the output pin corresponding to the digital signal input pin CBL. The output high level is VM and the output low level is VSS.

AT, BT, CT are the digital signal output pins of the three level shifters 14, wherein AT is the output pin corresponding to the digital signal input pin ATL, BT is the output pin corresponding to the digital signal input pin BTL, and CT is the output pin corresponding to the digital signal input pin CTL. The high levels of the output digital signals can be set via the input voltages of the pins VDAT, VDBT, VDCT respectively, while the low levels of the output digital signals can be set via the input voltages of the pins VSAT, VSBT, VSCT.

VDD and VSS are the positive power and the negative power for the logic circuit 11 respectively. VDAT is the high level output voltage of the digital signal output pin AT while VSAT is the low level output voltage of the digital signal output pin AT. VDBT is the high level output voltage of the digital signal output pin BT while VSBT is the low level output voltage of the digital signal output pin BT. VDCT is the high level output voltage of the digital signal output pin CT while VSCT is the low level output voltage of the digital signal output pin CT.

VM is the high level output voltage of the digital signal output pins AB, BB, CB, while VSS is the low level output voltage of the digital signal output pins AB, BB, CB.

The digital signal input pins ATL, BTL, CTL are connected to the voltage VSS via seriesly connected resistors so as to prevent the input pins ATL, BTL, CTL from being in a floating state when no signals are input thereto. Hence, when no signals are input to the input pins ATL, BTL, CTL, the voltage VSS will be regarded as the input thereto. When the input voltage of the input pins ATL, BTL, CTL is between VIH and VDD, it is regarded as the logic “high”, wherein VIH represents the minimum voltage for the input voltage to be regarded as the logic “high”. When the input voltage of the input pins ATL, BTL, CTL is between VSS and VIL, it is regarded as the logic “low”, wherein VIL represents the maximum voltage for the input voltage to be regarded as the logic “low”. In the digital circuit, the logic “high” and the logic “low” might be defined as “1” and “0” respectively, or defined as opposite logic, i.e. the logic “high” and the logic “low” are defined as “0” and “1” respectively.

The digital signal input pins ABL, BBL, CBL are connected to the voltage VDD via seriesly connected resistors so as to prevent the input pins ABL, BBL, CBL from being in a floating state when no signals are input thereto. Hence, when no signals are input to the input pins ABL, BBL, CBL, the voltage VDD will be regarded as the input thereto. When the input voltage of the input pins ABL, BBL, CBL is between VIH and VDD, it is regarded as the logic “high”, wherein VIH represents the minimum voltage for the input voltage to be regarded as the logic “high”. When the input voltage of the input pins ABL, BBL, CBL is between VSS and VIL, it is regarded as the logic “low”, wherein VIL represents the maximum voltage for the input voltage to be regarded as the logic “low”. In the digital circuit, the logic “high” and the logic “low” might be defined as “1” and “0” respectively, or defined as opposite logic, i.e. the logic “high” and the logic “low” are defined as “0” and “1” respectively.

When the input voltage of the input pins ATL, BTL, CTL is between VSS and VIL, it is regarded by the logic circuit 11 as “0”. When the input voltage of the input pins ATL, BTL, CTL is between VIH and VDD, it is regarded by the logic circuit 11 as “1”.

There are horizontal lines above the respective names of the input pins ABL, BBL, CBL, which represent opposite logic. That is, when the input voltage of the input pins ABL, BBL, CBL is between VSS and VIL, it is regarded by the logic circuit 11 as “1”, while when the input voltage of the input pins ABL, BBL, CBL is between VIH and VDD, it is regarded by the logic circuit 11 as “0”.

When the input voltage of the input pin ATL is regarded by the logic circuit 11 as “1”, the output pin AT outputs the voltage VDAT. When the input voltage of the input pin ATL is regarded by the logic circuit 11 as “0”, the output pin AT outputs the voltage VSAT.

When the input voltage of the input pin BTL is regarded by the logic circuit 11 as “1”, the output pin BT outputs the voltage VDBT. When the input voltage of the input pin BTL is regarded by the logic circuit 11 as “0”, the output pin BT outputs the voltage VSBT.

When the input voltage of the input pin CTL is regarded by the logic circuit 11 as “1”, the output pin CT outputs the voltage VDCT. When the input voltage of the input pin CTL is regarded by the logic circuit 11 as “0”, the output pin CT outputs the voltage VSCT.

When the input voltage of the input pin ABL is regarded by the logic circuit 11 as “1”, the output pin AB outputs the voltage VM. When the input voltage of the input pin ABL is regarded by the logic circuit 11 as “0”, the output pin AB outputs the voltage VSS.

When the input voltage of the input pin BBL is regarded by the logic circuit 11 as “1”, the output pin BB outputs the voltage VM. When the input voltage of the input pin BBL is regarded by the logic circuit 11 as “0”, the output pin BB outputs the voltage VSS.

When the input voltage of the input pin CBL is regarded by the logic circuit 11 as “1”, the output pin CB outputs the voltage VM. When the input voltage of the input pin CBL is regarded by the logic circuit 11 as “0”, the output pin CB outputs the voltage VSS.

When the input voltages of the input pins ATL and ABL are regarded by the logic circuit 11 as “1” simultaneously, the output pins AT and AB output the voltages VSAT and VSS respectively.

When the input voltages of the input pins BTL and BBL are regarded by the logic circuit 11 as “1” simultaneously, the output pins BT and BB output the voltages VSBT and VSS respectively.

When the input voltages of the input pins CTL and CBL are regarded by the logic circuit 11 as “1” simultaneously, the output pins CT and CB output the voltages VSCT and VSS respectively.

When the voltage VM is less than an internally set voltage turning point, the entire circuit will be reset. At this time, the output pins AT, BT, CT output the voltages VSAT, VSBT, VSCT respectively, and the output pins AB, BB, CB output the voltage VSS respectively.

In conclusion, the present invention provides 2N level shifters in an integrated circuit or an integrated circuit package, wherein N level shifters will convert the voltage of the input digital signal into output voltages with different levels, and the other N level shifters will convert the voltage of the input digital into a plurality of output voltages which can be set by the user. External pins are provided for setting the plurality of output voltages. Therefore, the present invention effectively solves the problems and drawbacks in the prior art, and thus it fits the demand of the industry and is industrially valuable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. An integrated circuit, comprising:
N level shifting devices, each of which receives a first digital signal and a second digital signal and comprises:
a first level shifter converting a first voltage of the first digital signal into a third voltage and converting a second voltage of the first digital signal into a fourth voltage; and
a second level shifter converting a first voltage of the second digital signal into a fifth voltage and converting a second voltage of the second digital signal into a sixth voltage.

2. An integrated circuit as claimed in claim 1, further comprising at least one logic circuit receiving the first digital signal and electrically connected to the first level shifter.

3. An integrated circuit as claimed in claim 2, wherein the logic circuit further receives the second digital signal and is electrically connected to the second level shifter.

4. An integrated circuit as claimed in claim 2, wherein the logic circuit is electrically connected to a low voltage protecting device.

5. An integrated circuit as claimed in claim 1, further comprising a first driver electrically connected to the first level shifter and outputting the third voltage and the fourth voltage.

6. An integrated circuit as claimed in claim 4, further comprising a second driver electrically connected to the second level shifter and outputting the fifth voltage and the sixth voltage.

7. An integrated circuit as claimed in claim 1, wherein N is an integer greater than or equal to 2.

8. An integrated circuit as claimed in claim 1, wherein the first voltage of the first signal and the second voltage of the first signal are input voltages of the first level shifter.

9. An integrated circuit as claimed in claim 8, wherein the first voltage of the first digital signal is a low level voltage, and the second voltage of the first digital signal is a high level voltage.

10. An integrated circuit as claimed in claim 9, wherein the first voltage of the first digital signal is a logic “0” signal, and the second voltage of the first digital signal is a logic “1” signal.

11. An integrated circuit as claimed in claim 9, wherein the first voltage of the first digital signal is a logic “1” signal, and the second voltage of the first digital signal is a logic “0” signal.

12. An integrated circuit as claimed in claim 1, wherein the third voltage and the fourth voltage are output voltages of the first level shifter.

13. An integrated circuit as claimed in claim 1, wherein the third voltage is a low level voltage, and the fourth voltage is a high level voltage.

14. An integrated circuit as claimed in claim 13, wherein the third voltage is a logic “0” signal, and the fourth voltage is a logic “1” signal.

15. An integrated circuit as claimed in claim 13, wherein the third voltage is a logic “1” signal, and the fourth voltage is a logic “0” signal.

16. An integrated circuit as claimed in claim 1, wherein the first voltage of the second digital signal and the second voltage of the second digital signal are input voltages of the second level shifter.

17. An integrated circuit as claimed in claim 16, wherein the first voltage of the second digital signal is a low level voltage, and the second voltage of the second digital signal is a high level voltage.

18. An integrated circuit as claimed in claim 17, wherein the first voltage of the second digital signal is a logic “0” signal, and the second voltage of the second digital signal is a logic “1” signal.

19. An integrated circuit as claimed in claim 17, wherein the first voltage of the second digital signal is a logic “1” signal, and the second voltage of the second digital signal is a logic “0” signal.

20. An integrated circuit as claimed in claim 1, wherein the fifth voltage and the sixth voltage are output voltages of the second level shifter.

21. An integrated circuit as claimed in claim 1, wherein the fifth voltage is a low level voltage, and the sixth voltage is a high level voltage.

22. An integrated circuit as claimed in claim 21, wherein the fifth voltage is a logic “0” signal, and the sixth voltage is a logic “1” signal.

23. An integrated circuit as claimed in claim 21, wherein the fifth voltage is a logic “1” signal, and the sixth voltage is a logic “0” signal.

24. An integrated circuit package, comprising:
N level shifting devices, each of which receives a first digital signal and a second digital signal and comprises:
a first level shifter converting a first voltage of the first digital signal into a third voltage and converting a second voltage of the first digital signal into a fourth voltage; and
a second level shifter converting a first voltage of the second digital signal into a fifth voltage and converting a second voltage of the second digital signal into a sixth voltage.

25. An integrated circuit, comprising:
N level shifting devices, each of which receives a first digital signal and a second digital signal and comprises:
a first level shifter electrically connected to a high level pin and a low level pin, wherein the high level pin is provided for the first level shifter to output a first high level voltage, and the low level pin is provided for the first level shifter to output a first low level voltage; and
a second level shifter electrically connected to a first pin and a second pin, wherein the first pin is provided for the second level shifter to output a second high level voltage, and the second pin is provided for the second level shifter to output a second low level voltage.

26. An integrated circuit as claimed in claim 25, further comprising at least one logic circuit receiving the first digital signal and electrically connected to the first level shifter.

27. An integrated circuit as claimed in claim 26, wherein the logic circuit further receives the second digital signal and is electrically connected to the second level shifter.

28. An integrated circuit as claimed in claim 26, wherein the logic circuit is electrically connected to a low voltage protecting device.

29. An integrated circuit as claimed in claim 25, further comprising a positive power pin and a negative power pin.

30. An integrated circuit as claimed in claim 29, wherein the positive power pin and the negative power pin provide powers for the first digital signal, wherein the powers are provided for the logic circuit to decide whether the first digital signal is a high level or a low level.

31. An integrated circuit as claimed in claim 29, wherein the positive power pin and the negative power pin provide powers for the second digital signal, wherein the powers are provided for the logic circuit to decide whether the second digital signal is a high level or a low level.

32. An integrated circuit as claimed in claim 25, wherein N is an integer greater than or equal to 2.

33. An integrated circuit package, comprising:
N level shifting devices, each of which receives a first digital signal and a second digital signal and comprises:
a first level shifter electrically connected to a high level pin and a low level pin, wherein the high level pin is provided for the first level shifter to output a first high level voltage, and the low level pin is provided for the first level shifter to output a first low level voltage; and
a second level shifter electrically connected to a first pin and a second pin, wherein the first pin is provided for the second level shifter to output a second high level voltage, and the second pin is provided for the second level shifter to output a second low level voltage.
